(19) United States
(12) Patent Application Publication
(10) Pub. No.: US 2012/0153527 A1
(43) Pub. Date: Jun. 21, 2012

(54) PROCESS FOR MANUFACTURING A STAND-ALONE THIN FILM

(75) Inventors: Debasish Banerjee, Ann Arbor, MI (US); Songtao Wu, Ann Arbor, MI (US); Minjuan Zhang, Ann Arbor, MI (US); Masahiko Ishii, Okazaki City (JP)

(73) Assignee: Toyota Motor Engineering & Manufacturing North America, Inc., Erlanger, KY (US)

(21) Appl. No.: 12/974,325

(22) Filed: Dec. 21, 2010

(51) Int. Cl. B29C 35/02; C23C 16/01

(52) U.S. Cl. 264/80; 264/81

(57) ABSTRACT

A process for manufacturing stand-alone thin films is provided. The process includes providing a substrate, depositing a carbon-containing sacrificial layer onto the substrate and the depositing a thin film onto the carbon-containing sacrificial layer. Thereafter, the substrate, carbon-containing sacrificial layer and thin film structure are exposed to oxygen at an elevated temperature. The oxygen reacts with the carbon-containing sacrificial layer to produce carbon dioxide and remove carbon from the sacrificial layer, thereby generally burning away the sacrificial layer and affording for an intact stand-alone thin film to separate from the substrate.

### FIELD OF THE INVENTION

The present invention is related to a process for manufacturing a thin film, and in particular, to a process for manufacturing a stand-alone thin film.

### BACKGROUND OF THE INVENTION

The production of thin films on substrates is well known. For example, thin films produced on metals, semiconductors, oxides, and the like for protection of an underlying substrate, enhancement of surface properties for a component, aesthetic purposes, etc. are known. However, processes for producing thin films that are not attached to a substrate, that is a stand-alone thin film, are not well known. In addition, known processes for producing such a thin film require corrosive etching gases. For example, U.S. Pat. No. 6,331,260 discloses a process in which a thin film is vapor deposited onto a single crystal substrate wafer, the substrate wafer subsequently removed by chemically etching with an etch gas with complicated and/or expensive equipment required to handle the sample and/or the etch gas. Therefore, an unproved process that allows for the manufacture of stand-alone thin films would be desirable.

### SUMMARY OF THE INVENTION

A process for manufacturing stand-alone thin films is provided. The process includes providing a substrate, depositing a carbon-containing sacrificial layer onto the substrate and the depositing a thin film onto the carbon-containing sacrificial layer. Thereafter, the substrate, carbon-containing sacrificial layer and thin film structure are exposed to oxygen at an elevated temperature. The oxygen reacts with the carbon-containing sacrificial layer to produce carbon dioxide and remove carbon from the sacrificial layer, thereby generally burning away the sacrificial layer and affording for an intact stand-alone thin film to separate from the substrate.

In some instances, the substrate can be an oxide such as silicon oxide. In addition, the carbon-containing layer can be a polymer layer, a carbon layer, and the like. The carbon-containing layer can be deposited using a vacuum deposition technique, a sol-gel technique and/or a layer-by-layer technique.

The thin film can have a multilayer structure, e.g. a multilayer stack that provides an omnidirectional structural color, an omnidirectional infrared reflector, and/or an omnidirectional ultraviolet reflector. The process can use air to expose the substrate, carbon-containing sacrificial layer and thin film to oxygen and the elevated temperature can be greater than 300° C. In some instances, the elevated temperature is greater than 400° C., while in other instances the elevated temperature is greater than 500° C.

### BRIEF DESCRIPTION OF THE DRAWINGS

FIG. 1 is a schematic diagram of a process according to an embodiment of the present invention;

FIG. 2 is a schematic illustration of the manufacture of a stand-alone thin film produced according to an embodiment of the present invention;

FIG. 3 is a schematic illustration of the manufacture of a stand-alone multilayer thin film produced according to an embodiment of the present invention; and

FIG. 4 is an optical microscopy image of flakes made from a stand-alone thin film produced according to an embodiment of the present invention.

### DETAILED DESCRIPTION OF THE INVENTION

The present invention discloses a process for manufacturing a stand-alone thin film. Such stand-alone thin films can be subjected to crushing, grinding, and/or sieving in order to produce particles in the form of flakes, the flakes being used as a pigment. Therefore, the present invention has utility for the production of flakes and/or pigments.

The process includes depositing a carbon-containing sacrificial layer onto a substrate followed by depositing a thin film onto the carbon-containing sacrificial layer. Thereafter, the substrate with the carbon-containing sacrificial layer deposited thereon and the thin film deposited onto the sacrificial layer are exposed to oxygen at an elevated temperature. The exposure of the substrate, sacrificial layer and thin film to oxygen at the elevated temperature affords for the oxygen to react with the sacrificial layer to produce carbon dioxide and essentially burn away the carbon-containing sacrificial layer. It is appreciated that removal and/or burning away of the sacrificial layer results in a “stand-alone” thin film, i.e. a thin film that has been removed from the substrate and is free-standing—independent and/or unattached from the substrate. In addition, the thin film can be intact, that is present in its as-deposited form and generally not present as broken and/or crushed-up particles and the like.

The substrate can be any material known to those skilled in the art, such as a metal, an oxide, a nitride, a sulfide, etc. As such, the substrate is generally inert to oxygen at an elevated temperature, or in the alternative, forms a generally protective layer when exposed to the oxygen at the elevated temperature. For example and for illustrative purposes, the substrate can be a silicon oxide such as silica which does not degrade when exposed to oxygen at the elevated temperature, or in the alternative, aluminum which forms a thin protective oxide scale when exposed to oxygen at the elevated temperature.

The carbon-containing sacrificial layer can be a polymer layer, or in the alternative, a carbon layer. For example and for illustrative purposes only, the carbon-containing sacrificial layer can be a carbon layer deposited using a vacuum deposition technique and/or a sol-gel technique. If the carbon-containing sacrificial layer is a polymer layer, the polymer layer can be deposited onto the substrate using a sol-gel technique and/or a layer-by-layer technique.

The thin film can be deposited onto the carbon-containing sacrificial layer using any method or process known to those skilled in the art such as a vacuum deposition process, a sol-gel process, and/or a layer-by-layer process. The thin film may or may not have a multilayer structure. For example and for illustrative purposes only, the thin film can have a multilayer structure in the form of an omnidirectional structural color, an omnidirectional infrared reflector, and/or an omnidirectional ultraviolet reflector. Omnidirectional structural colors, omnidirectional infrared reflectors, and/or omnidirectional ultraviolet reflectors such as those disclosed in commonly assigned U.S. patent application Ser. Nos. 11/837,529; 12/388,395; and 12/389,221 can be the type of thin film deposited onto the carbon-containing sacrificial layer.

The oxygen used to react with the carbon-containing sacrificial layer can be provided as the oxygen in air, as an oxygen-enriched air, or as pure oxygen. The elevated temperature can be equal to or greater than 300° C., 400° C., 500° C., 600° C., 700° C. and/or 800° C.

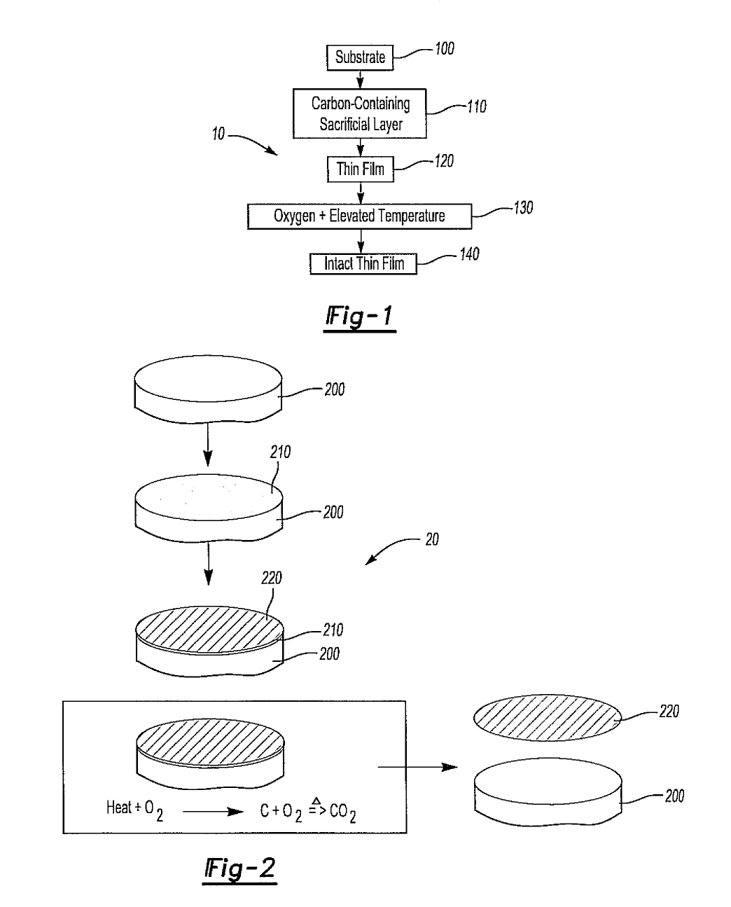

Turning now to FIG. 1, a schematic diagram illustrating a process according to an embodiment of the present invention is shown generally at reference numeral 10. The process 10 includes providing a substrate at step 100 and depositing a carbon-containing sacrificial layer onto the substrate at step 110. A thin film is deposited onto the carbon-containing sacrificial layer at step 120 and the substrate, carbon-containing sacrificial layer and thin film structure are exposed to oxygen at an elevated temperature at step 130. As stated above, contact between the carbon-containing sacrificial layer and the oxygen at elevated temperature results in a chemical reaction such as:

C+O₂(g)<=>CO₂(g)

to form carbon dioxide gas that affords for the removal of the carbon-containing sacrificial layer from between the substrate and the thin film. It is appreciated that removal of the carbon-containing sacrificial layer affords for the thin film to be removed and/or separated from the substrate. The thin film can be intact and is stand-alone.

Turning now to FIG. 2, a schematic illustration of the manufacture of a stand-alone thin film is shown generally at reference 20. The process 20 includes providing a substrate 200 and depositing a carbon-containing sacrificial layer 210 onto the substrate 200. Thereafter, a thin film 220 is deposited onto the sacrificial layer 210. The substrate 200, sacrificial layer 210 and thin film 220 are then exposed to heat and oxygen, the oxygen reacting with carbon from the sacrificial layer 210 to produce carbon dioxide gas and essentially burn away the sacrificial layer. Burning away of the sacrificial layer 210 thus results in the thin film 220 being removed from the substrate 200. The thin film 220 can be intact and in this manner a stand-alone thin film is provided.

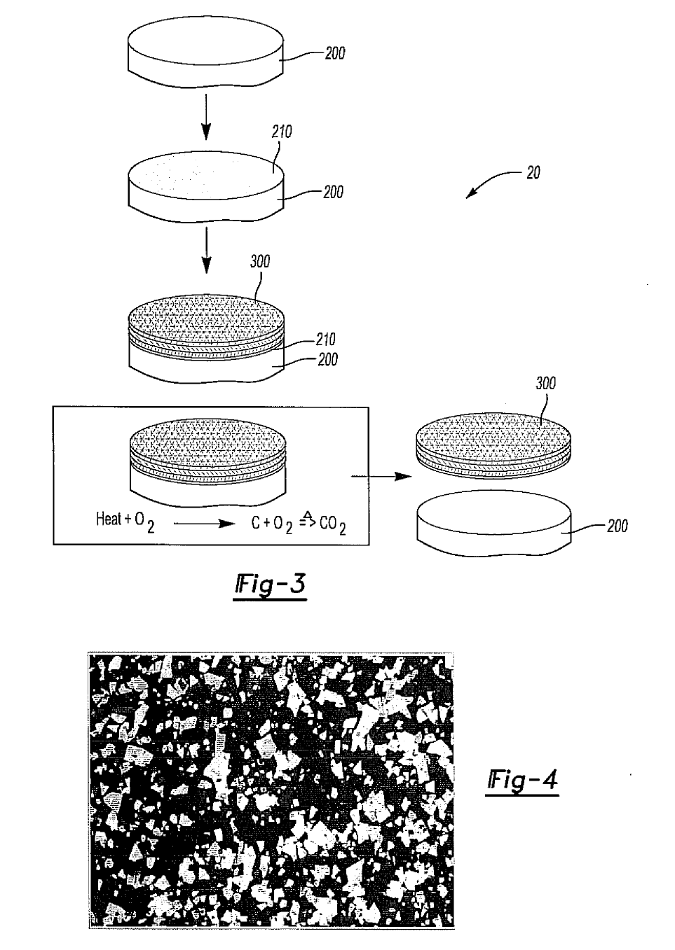

Referring now to FIG. 3, a schematic illustration of the production of a stand-alone multilayer film is provided. A carbon-containing sacrificial layer 210 is deposited onto the substrate 200, followed by deposition of a multilayer thin film 300 onto the sacrificial layer 210. Similar to the process illustrated in FIG. 2, heat plus oxygen is provided such that the sacrificial layer 210 reacts with oxygen at an elevated temperature to produce carbon dioxide gas. Again, the sacrificial layer 210 is essentially burned away and thus affords for a stand-alone and intact multilayer film 300.

It is appreciated that the thin film 220 and/or the multilayer film 300 can be sectioned while still attached to the sacrificial layer 210. For example and for illustrative purposes only, a knife such as a diamond-tipped knife can be used to section the thin film 220 and/or the multilayer film 300 before exposure to the heat and oxygen with a plurality of stand-alone thin films provided by the process disclosed herein.

In order to better illustrate and teach the present invention, an illustrative example is provided.

### Example

Multilayer structural colored thin films having major components of titania (TiO₂), silica (SiO₂), and hafnia (HfO₂) were deposited onto a silica wafer that had a carbon-containing sacrificial layer thereon. Stated differently, a carbon layer was deposited onto the silica wafer and was present at the interface between the silica wafer and the multilayer structural colored film. Thereafter, the multilayer structural colored films were sectioned into small rectangular pieces by scribing of the film with a diamond knife. The silica wafer with the carbon sacrificial layer and multilayer structural colored film was then placed in a furnace and heated to 800° C. for 12 hours in an air atmosphere.

After cooling, intact sections of the multilayer structural colored film were found to be detached from the substrate. The yield of the process was approximately 100%. The sections of the stand-alone multilayer structural colored films were then subjected to crushing, grinding, and sieving in order to produce flakes exhibiting an omnidirectional structural color. An example of the flakes produced according to the process is shown in FIG. 4. In this manner, a simple and cost-effective process is provided for the manufacture of stand-alone and/or intact thin films.

The invention is not restricted to the illustrative examples and/or embodiments described above. The examples and/or embodiments are not intended as limitations on the scope of the invention. Methods, processes, apparatus, compositions, and the like described herein are exemplary and not intended as limitations on the scope of the invention. Changes herein and other uses will occur to those skilled in the art. The scope of the invention is defined by the scope of the claims.

We claim:

1. A process for manufacturing a stand-alone thin film, the process comprising:
providing a substrate;
depositing a carbon-containing sacrificial layer onto the substrate;
depositing a thin film onto the carbon-containing sacrificial layer;
exposing the substrate with the carbon-containing sacrificial layer and the thin film to oxygen at an elevated temperature, the oxygen reacting with the carbon-containing sacrificial layer to produce carbon dioxide and resulting in the thin film being removed from the substrate intact.

2. The process of claim 1, wherein the substrate is an oxide.

3. The process of claim 2, wherein the oxide is silicon oxide.

4. The process of claim 1, wherein the carbon-containing sacrificial layer is a polymer layer.

5. The process of claim 1, wherein the carbon-containing sacrificial layer is a carbon layer.

6. The process of claim 1, wherein the carbon-containing sacrificial layer is deposited using a vacuum deposition technique.

7. The process of claim 1, wherein the carbon-containing sacrificial layer is deposited using a sol-gel technique.

8. The process of claim 1, wherein the carbon-containing sacrificial layer is deposited using a layer-by-layer technique.

9. The process of claim 1, wherein the thin film has a multilayered structure.

10. The process of claim 9, wherein the thin film is an omnidirectional structural color.

11. The process of claim 9, wherein the thin film is an omnidirectional infrared reflector.

12. The process of claim 9, wherein the thin film is an omnidirectional ultraviolet reflector.

13. The process of claim 9, wherein the thin film is an omnidirectional infrared and ultraviolet reflector.

14. The process of claim 1, wherein air is used to expose the substrate with the carbon sacrificial layer and the thin film to oxygen.

15. The process of claim 1, wherein the elevated temperature is greater than 300° C.

16. The process of claim 1, wherein the elevated temperature is greater than 400° C.

17. The process of claim 1, wherein the elevated temperature is greater than 500° C.

18. The process of claim 1, wherein the substrate with the carbon-containing sacrificial layer and the thin film are exposed to air at a temperature greater than 400° C.
